(19) United States
(12) Patent Application Publication
(10) Pub. No.: US 2013/0141243 A1
(43) Pub. Date: Jun. 6, 2013

(54) Server

(71) Applicant: Anthony Watts, Chico, CA (US)

(72) Inventor: Anthony Watts, Chico, CA (US)

(21) Appl. No.: 13/309,917

(22) Filed: Dec. 2, 2011

(51) Int. Cl. G08B 17/00; H05K 7/20; H05K 5/02; G06F 1/20; G06F 1/16

(52) U.S. Cl. 340/584; 361/679.48; 361/679.02; 312/223.2; 312/236

(57) ABSTRACT

A server comprises a holding chassis. The holding chassis comprises a front open end and a back open end. A cable interface area is disposed in the back open end. A fan is disposed in the front open end. The fan is configured to force air form the front open end to the back open end. The holding chassis also comprises a computer rack mounting system being configured to hold a plurality of computers. The server also comprises a blade tray being configured to be removably joined to the rack mounting system. The blade tray comprises a computer and a DC to DC power converter. The server also comprises a power supply shelf being configured to hold a power supply for the blade tray and a power supply for the fan. For alternate off-grid operation, the server may also comprises a DC power distribution box being configured to distribute DC power from external sources.

### FEDERALLY SPONSORED RESEARCH OR DEVELOPMENT

Not applicable.

REFERENCE TO SEQUENCE LISTING, A TABLE, OR A COMPUTER LISTING APPENDIX

Not applicable.

### COPYRIGHT NOTICE

A portion of the disclosure of this patent document contains material that is subject to copyright protection. The copyright owner has no objection to the facsimile reproduction by anyone of the patent document or patent disclosure as it appears in the Patent and Trademark Office, patent file or records, but otherwise reserves all copyright rights whatsoever.

### FIELD OF THE INVENTION

One or more embodiments of the invention generally relate to computer servers. More particularly, the invention relates to a modular blade server system.

### BACKGROUND OF THE INVENTION

The following background information may present examples of specific aspects of the prior art (e.g., without limitation, approaches, facts, or common wisdom) that, while expected to be helpful to further educate the reader as to additional aspects of the prior art, is not to be construed as limiting the present invention, or any embodiments thereof, to anything stated or implied therein or inferred thereupon. Blade servers are computer servers that are typically designed to use less energy and occupy less space than a typical computer server. A blade case or blade chassis can hold multiple blade servers and often provides features such as, but not limited to, cooling, connections, networking, etc. Typically, industry standard practice for blade server system design typically calls for access to controls and removal of blades at the front of the chassis with power and data cables at rear so that the cables may be enclosed neatly in the rack cabinet. Cooling airflow from the front to the rear of the chassis is also standard for blade server systems.

The Mini-ITX and Thin Mini-ITX class of motherboards is an emerging new force for low cost and low power computer deployment. By way of educational background, another aspect of the prior art generally useful to be aware of is that many currently existing blade servers for the Mini-ITX motherboard platform are reversed from normal practice with the cables located in the front and the fans in the rear. Also, many of these current blade servers comprise proprietary components, which is believed to limit flexibility.

In view of the foregoing, it is clear that these traditional techniques are not perfect and leave room for more optimal approaches.

### BRIEF DESCRIPTION OF THE DRAWINGS

The present invention is illustrated by way of example, and not by way of limitation, in the figures of the accompanying drawings and in which like reference numerals refer to similar elements and in which:

FIGS. 1A, 1B and 1C illustrate an exemplary blade tray holding chassis that can hold multiple blade trays, in accordance with an embodiment of the present invention.

FIG. 1A is a front perspective view. FIG. 1B is a rear perspective view, and FIG. 1C is a transparent front perspective view;

FIG. 2A is a rear perspective view of an exemplary power supply shelf, in accordance with an embodiment of the present invention. FIG. 2B is a rear perspective view of an exemplary alternate DC power distribution box, in accordance with an embodiment of the present invention;

FIG. 3A is a cross sectional side view of an exemplary modular blade system in use with a typical rack-mounting system, powered by typical 120/240 volt AC wall power, in accordance with an embodiment of the present invention. FIG. 3B is a cross sectional side view of an exemplary modular blade system in use with a typical rack-mounting system powered by DC 12 volt alternate wind and solar power sources, in accordance with an embodiment of the present invention;

FIG. 4 is a side perspective view of an exemplary blade tray, in accordance with an embodiment of the present invention;

FIG. 5 is a side view of exemplary computer components mounted to a blade tray, in accordance with an embodiment of the present invention;

FIGS. 6A, 6B, 6C, 6D, and 6E illustrate an exemplary blade tray holding chassis holding multiple blade trays with a hinged door assembly in an open position, in accordance with an embodiment of the present invention for the Mini-ITX and Thin Mini-ITX form factors FIG. 6A is a front view. FIG. 6B is a cross sectional side view, and FIG. 6C is a diagrammatic rear view. FIG. 6D is a front view exemplary of a Thin Mini-ITX configuration and FIG. 6E is a rear view of a Thin Mini-ITX configuration; and

FIG. 7 illustrates an exemplary blade tray being removed from a blade tray holding chassis, in accordance with an embodiment of the present invention.

Unless otherwise indicated illustrations in the figures are not necessarily drawn to scale.

### DETAILED DESCRIPTION OF THE PREFERRED EMBODIMENTS

The present invention is best understood by reference to the detailed figures and description set forth herein.

Embodiments of the invention are discussed below with reference to the Figures. However, those skilled in the art will readily appreciate that the detailed description given herein with respect to these figures is for explanatory purposes as the invention extends beyond these limited embodiments. For example, it should be appreciated that those skilled in the art will, in light of the teachings of the present invention, recognize a multiplicity of alternate and suitable approaches, depending upon the needs of the particular application, to implement the functionality of any given detail described herein, beyond the particular implementation choices in the following embodiments described and shown. That is, there are numerous modifications and variations of the invention that are too numerous to be listed but that all fit within the scope of the invention. Also, singular words should be read as plural and vice versa and masculine as feminine and vice versa, where appropriate, and alternative embodiments do not necessarily imply that the two are mutually exclusive.

It is to be further understood that the present invention is not limited to the particular methodology, compounds, materials, manufacturing techniques, uses, and applications, described herein, as these may vary. It is also to be understood that the terminology used herein is used for the purpose of describing particular embodiments only, and is not intended to limit the scope of the present invention. It must be noted that as used herein and in the appended claims, the singular forms “a,” “an,” and “the” include the plural reference unless the context clearly dictates otherwise. Thus, for example, a reference to “an element” is a reference to one or more elements and includes equivalents thereof known to those skilled in the art. Similarly, for another example, a reference to “a step” or “a means” is a reference to one or more steps or means and may include sub-steps and subservient means. All conjunctions used are to be understood in the most inclusive sense possible. Thus, the word “or” should be understood as having the definition of a logical “or” rather than that of a logical “exclusive or” unless the context clearly necessitates otherwise. Structures described herein are to be understood also to refer to functional equivalents of such structures. Language that may be construed to express approximation should be so understood unless the context clearly dictates otherwise.

Unless defined otherwise, all technical and scientific terms used herein have the same meanings as commonly understood by one of ordinary skill in the art to which this invention belongs. Preferred methods, techniques, devices, and materials are described, although any methods, techniques, devices, or materials similar or equivalent to those described herein may be used in the practice or testing of the present invention. Structures described herein are to be understood also to refer to functional equivalents of such structures. The present invention will now be described in detail with reference to embodiments thereof as illustrated in the accompanying drawings.

From reading the present disclosure, other variations and modifications will be apparent to persons skilled in the art. Such variations and modifications may involve equivalent and other features which are already known in the art, and which may be used instead of or in addition to features already described herein.

Although Claims have been formulated in this application to particular combinations of features, it should be understood that the scope of the disclosure of the present invention also includes any novel feature or any novel combination of features disclosed herein either explicitly or implicitly or any generalization thereof, whether or not it relates to the same invention as presently claimed in any Claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable subcombination. The Applicants hereby give notice that new Claims may be formulated to such features and/or combinations of such features during the prosecution of the present application or of any further application derived therefrom.

References to “one embodiment,” “an embodiment,” “example embodiment,” “various embodiments,” etc., may indicate that the embodiment(s) of the invention so described may include a particular feature, structure, or characteristic, but not every embodiment necessarily includes the particular feature, structure, or characteristic. Further, repeated use of the phrase “in one embodiment,” or “in an exemplary embodiment,” do not necessarily refer to the same embodiment, although they may.

As is well known to those skilled in the art many careful considerations and compromises typically must be made when designing for the optimal manufacture of a commercial implementation any system, and in particular, the embodiments of the present invention. A commercial implementation in accordance with the spirit and teachings of the present invention may configured according to the needs of the particular application, whereby any aspect(s), feature(s), function(s), result(s), component(s), approach(es), or step(s) of the teachings related to any described embodiment of the present invention may be suitably omitted, included, adapted, mixed and matched, or improved and/or optimized by those skilled in the art, using their average skills and known techniques, to achieve the desired implementation that addresses the needs of the particular application.

A “computer” may refer to one or more apparatus and/or one or more systems that are capable of accepting a structured input, processing the structured input according to prescribed rules, and producing results of the processing as output. Examples of a computer may include: a computer; a stationary and/or portable computer; a computer having a single processor, multiple processors, or multi-core processors, which may operate in parallel and/or not in parallel; a general purpose computer; a supercomputer; a mainframe; a super mini-computer; a mini-computer; a workstation; a micro-computer; a server; a client; an interactive television; a web appliance; a telecommunications device with internet access; a hybrid combination of a computer and an interactive television; a portable computer; a tablet personal computer (PC); a personal digital assistant (PDA); a portable telephone; application-specific hardware to emulate a computer and/or software, such as, for example, a digital signal processor (DSP), a field-programmable gate array (FPGA), an application specific integrated circuit (ASIC), an application specific instruction-set processor (ASIP), a chip, chips, a system on a chip, or a chip set; a data acquisition device; an optical computer; a quantum computer; a biological computer; and generally, an apparatus that may accept data, process data according to one or more stored software programs, generate results, and typically include input, output, storage, arithmetic, logic, and control units.

It is to be understood that any exact measurements/dimensions or particular construction materials indicated herein are solely provided as examples of suitable configurations and are not intended to be limiting in any way. Depending on the needs of the particular application, those skilled in the art will readily recognize, in light of the following teachings, a multiplicity of suitable alternative implementation details.

A practical embodiment of the present invention provides a modular blade server system that comprises a blade tray holding chassis, one or more blade trays, and a separated power supply shelf. In some alternate embodiments, the system can be expanded as needed. In many practical embodiments up to 9 blade trays can be used in one blade tray holding chassis. In many practical embodiments, the blade tray holding chassis is a rack mounted computer housing that holds multiple self-contained individual “blade” computers on specialized blade trays that utilize computing components of extremely low power design and thus low cooling requirements. The chassis in many practical embodiments also comprises fans to providing forced air cooling to the populated blade trays. In many practical embodiments the computer component populated blade trays act as functioning computers and typically comprise a Mini-ITX form factor motherboard, one 2.5 inch or 3.5 inch form factor hard disk drive, one RAM memory module, one DC to DC converter board to convert the DC power applied at the rear of the chassis to the multiple voltages needed by the motherboard and hard disk drives, and control wiring and indicators for the motherboard. Many practical embodiments separate the power supplies from the computers by providing a separate rack mountable shelf for the power supplies, which minimizes the need for specialized cooling schemes and is believed to lower the cost of ownership and lower power consumption. Separating the power supplies also minimizes actions required for waste heat management inside the blade chassis. The power supply shelf in many practical embodiments can accommodate multiple power supplies, which may include, without limitation, an AC to DC power supply for each of the blade trays and an AC to DC power supply for the blade tray holding chassis. Many practical embodiments allow for flexible power sources and placement in venues outside of a standard computer server room. The design of some practical embodiments utilizing Mini-ITX and Thin Mini-ITX technology, which offers low power consumption, high computing component density, and enables computer server blade trays to operate on as little as 25 watts of power, providing computing function equivalent to systems that may be operating at 2 to 5 times the power consumption. Many practical embodiments are economically attractive due to their efficient cooling, low power requirement, industry standard computing component interchangeability, and high density of computing technology in rack space.

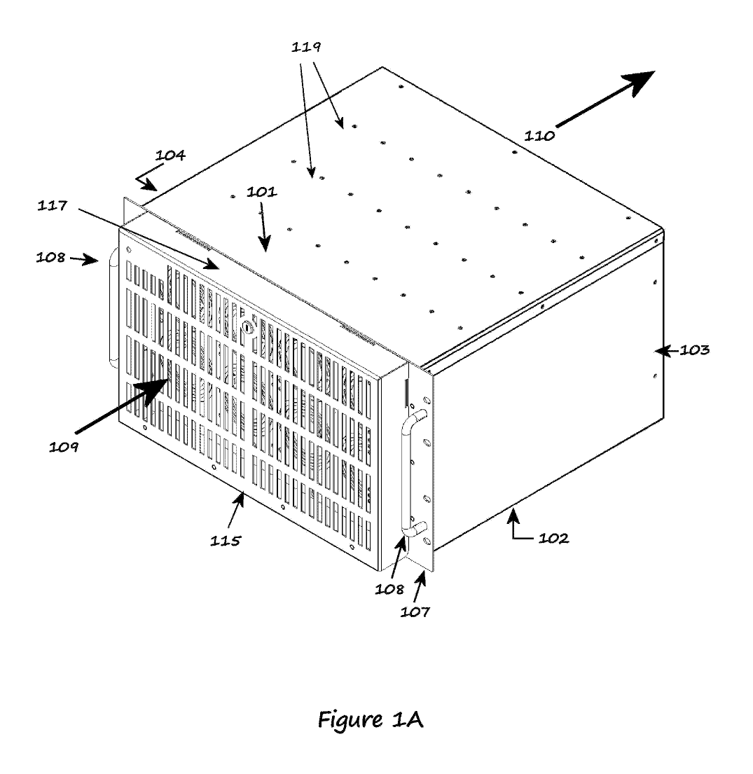

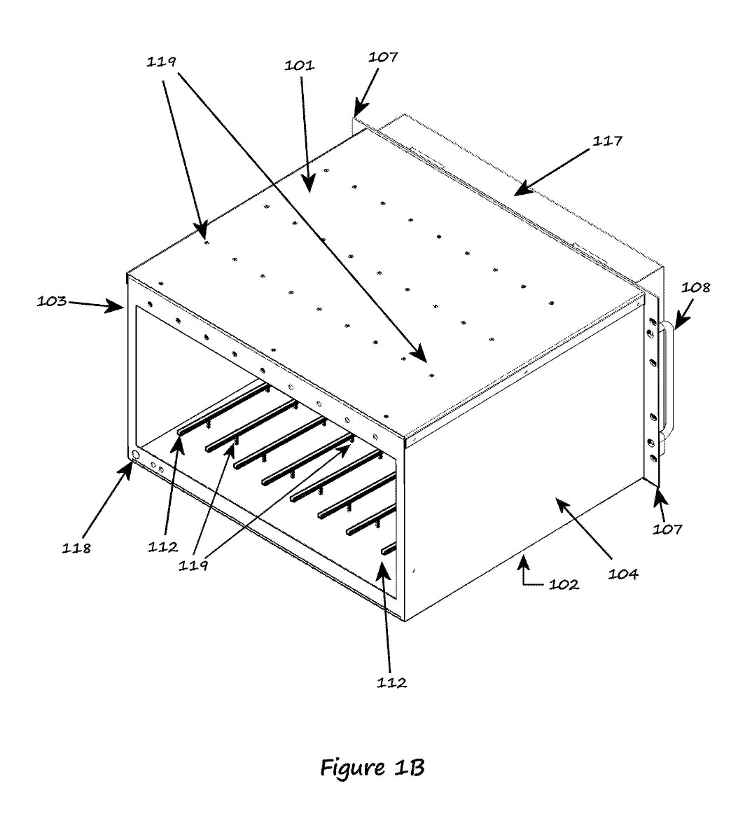

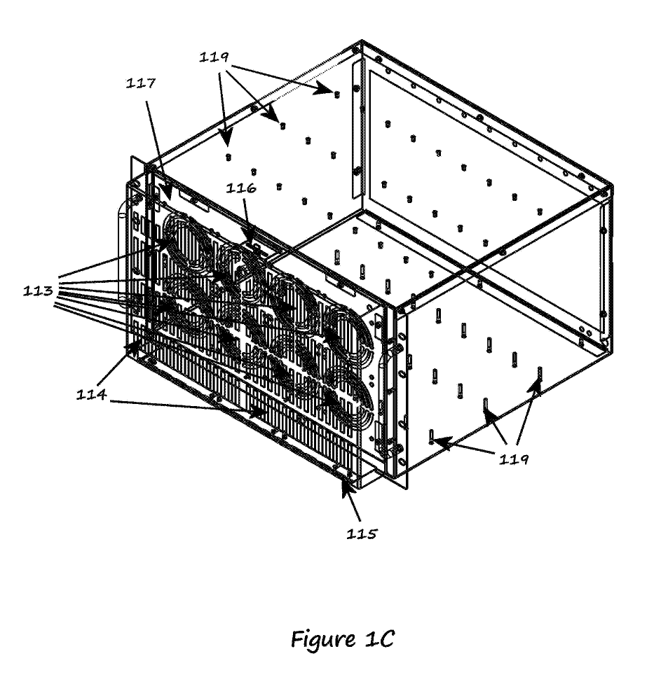

FIGS. 1A, 1B and 1C illustrate an exemplary blade tray holding chassis that can hold multiple blade trays, in accordance with an embodiment of the present invention.

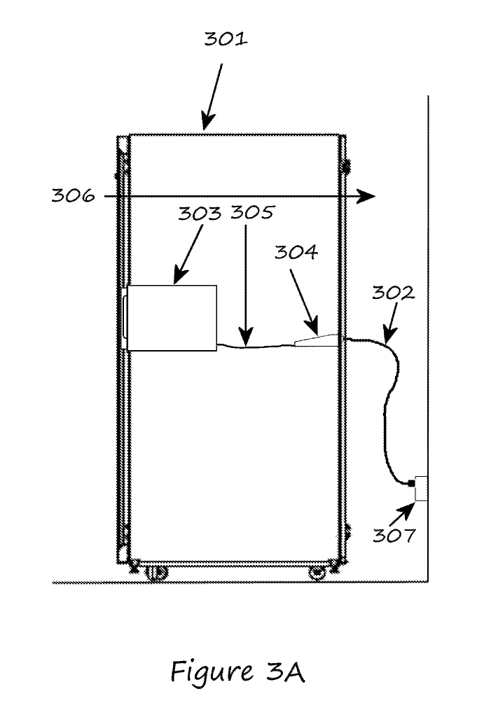

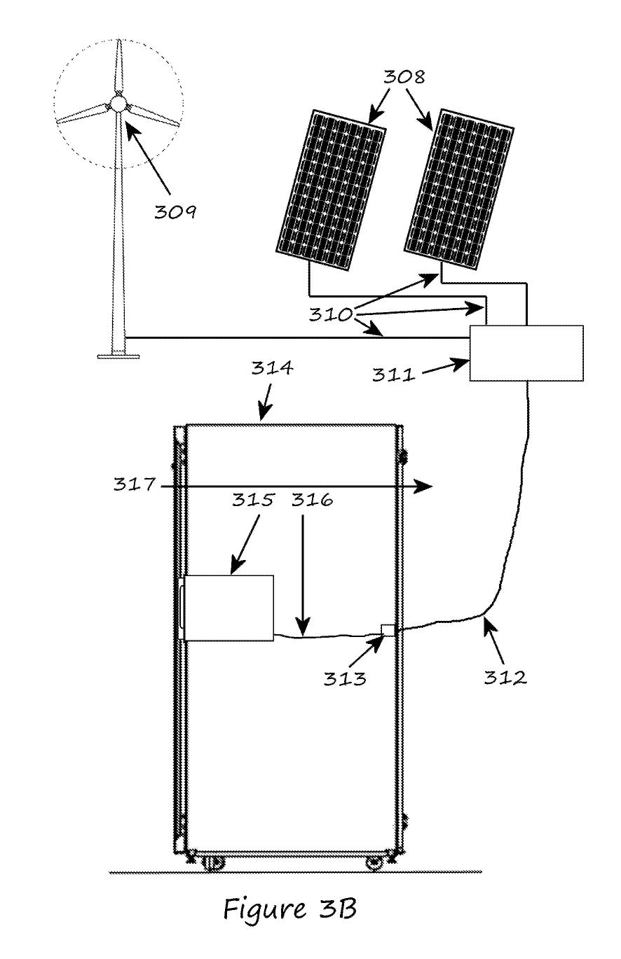

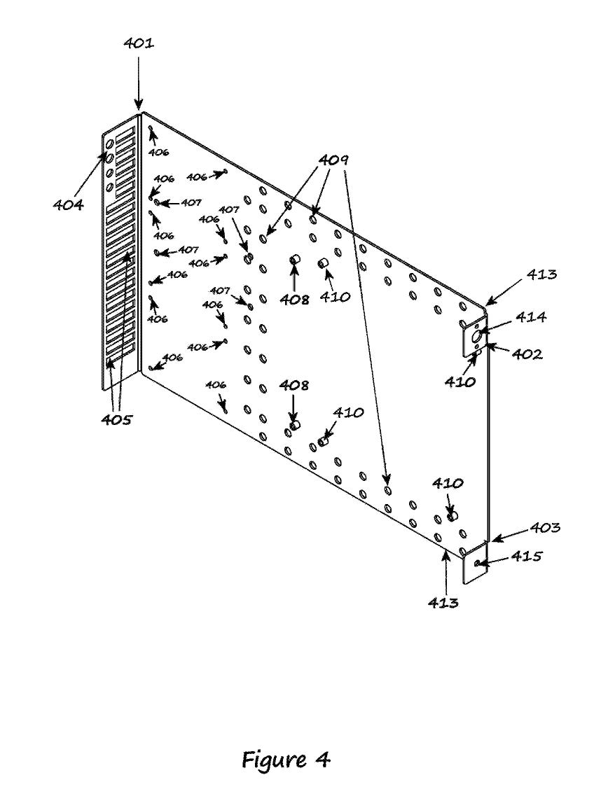

FIG. 1A is a front perspective view. FIG. 1B is a rear perspective view, and FIG. 1C is a transparent front perspective view. In the present embodiment, the blade tray holding chassis comprises a four sided metal enclosure with a top 101 and a bottom 102 with metal sides 103 and 104. The blade tray holding chassis also comprises mount brackets 107, which enable the blade tray holding chassis to be mounted to a typical rack-mounting system, as shown by way of example in FIG. 3, and rack mount handles 108. The design of the blade tray holding chassis provides for linear front to rear airflow, as illustrated by arrows 109 and 110, and generally does not require any airflow ducting or diversion. Referring to FIG. 1B, the entire rear of the blade tray holding chassis is open to provide unimpeded access to rear connectors on blade trays placed in the blade tray holding chassis and to provide free air flow out the rear. This generally makes the cooling process of dissipating waste heat from the active computer components more efficient. Blade trays, as shown by way of example in FIG. 4 can be inserted into the blade tray holding chassis on mounting rails 112. The front and rear of the blade trays are designed so that front to rear airflow is unimpeded while mounted inside the blade tray holding chassis, and thus the airflow interacts directly with the components most in need of heat dissipation. Mounting rails 112 are secured by screw standoffs 119 on top 101 and bottom 102 of the blade tray holding chassis. Standoffs 119 generally ensure that the blade trays are separated from top 101 and bottom 102 of the blade tray holding chassis so that virtually no air circulation is trapped by any barrier. Referring to FIG. 1A, handles 108 are provided to allow easy removal and handling of the blade tray holding chassis by a single person.

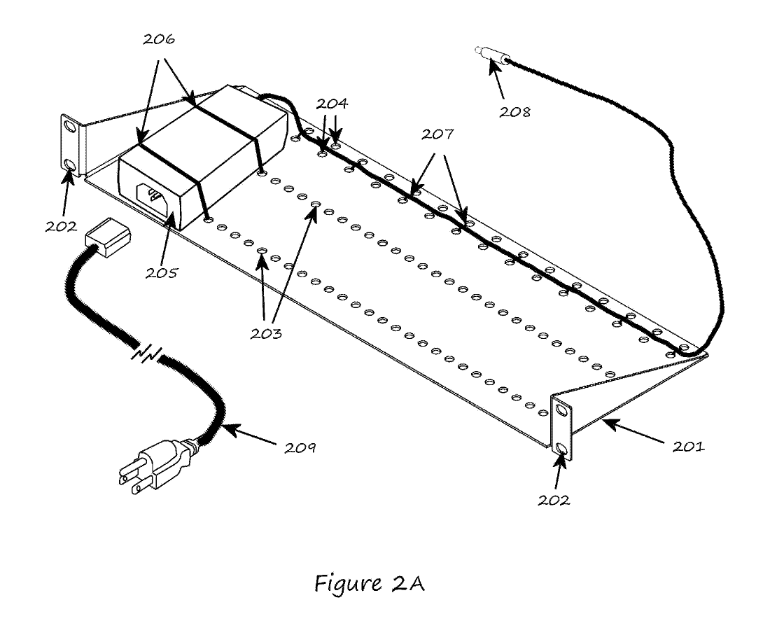

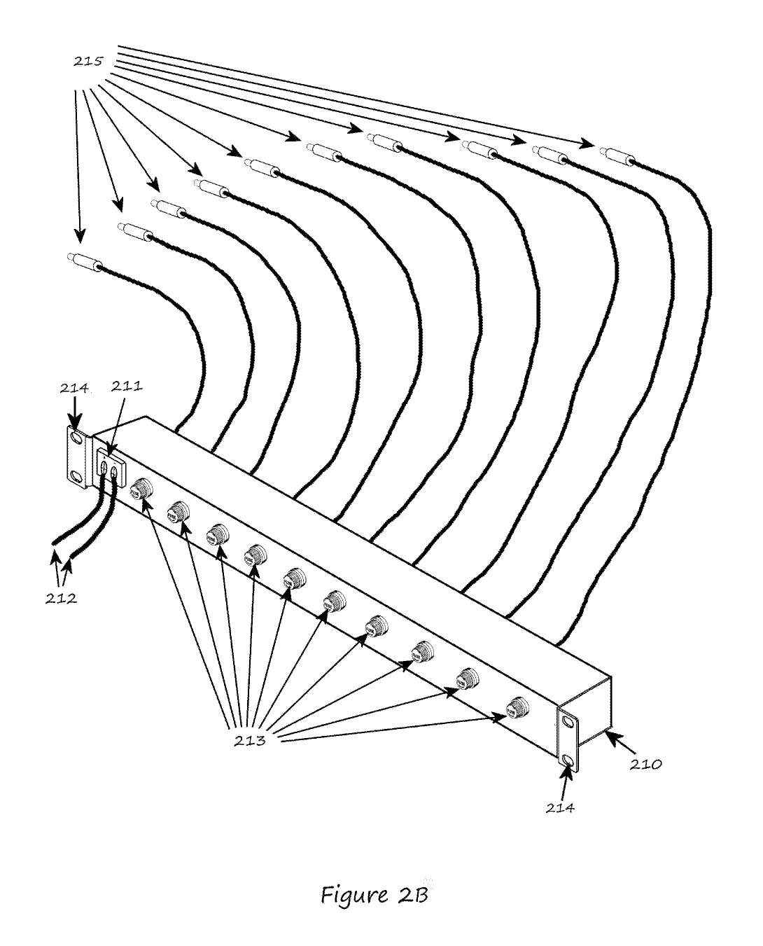

Referring to FIG. 1C, in the present embodiment, the blade tray holding chassis incorporates mounting cutouts for eight electrically powered airflow fans 113 for cooling that draw air through front air slots 114 such that a single fan failure will not cause a failure in a blade tray computer. This redundancy provides front to rear airflow for each blade tray even if one fan fails. Airflow fans 113 are mounted in a hinged door assembly 115 which is secured closed while in operation by a key and tab lock assembly 116 to a tab 117 on the blade tray holding chassis when door assembly 115 is closed, generally preventing removal, tampering, or accidental interaction with computer front panel controls. Referring to FIG. 1B, fans 113 are powered by the same 12 volt DC power supplies as the blade trays, with a coaxial power connector 118 provided to power the entire blade tray holding chassis at the rear of the chassis from an external 12 Volts DC power supply on a power supply shelf, as shown by way of example in FIGS. 2 and 3.

FIG. 2A is a rear perspective view of an exemplary power supply shelf 201, in accordance with an embodiment of the present invention. In the present embodiment power supply shelf 201 is separate from the chassis, and enables the entire blade tray holding chassis to be operated on 120/240 Volts AC power or DC power in the range of 12 to 16 volts DC. This unique feature allows the modular blade system to work in fixed applications (e.g., computer equipment rooms) or mobile applications (e.g., equipment trucks and vans) and to be powered by alternate power systems, such as, but not limited to, portable DC generators, DC batteries, solar power, or wind power where DC power is available rather than grid based AC power. Moreover, separating the power supplies from the chassis means the waste heat generated from the power supplies is located outside of the server case where it can typically be handled by standard server room air conditioning. This improves cooling efficiency and extends the life of computer components within the system. FIG. 2B is a rear perspective view of an exemplary alternate DC power distribution box 210, used for distributing DC power from such alternate sources.

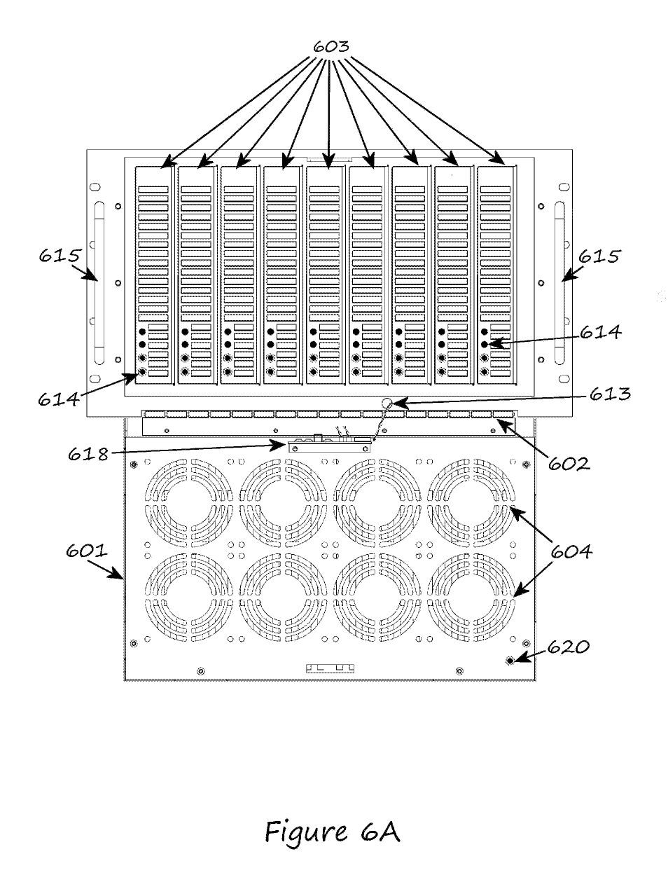

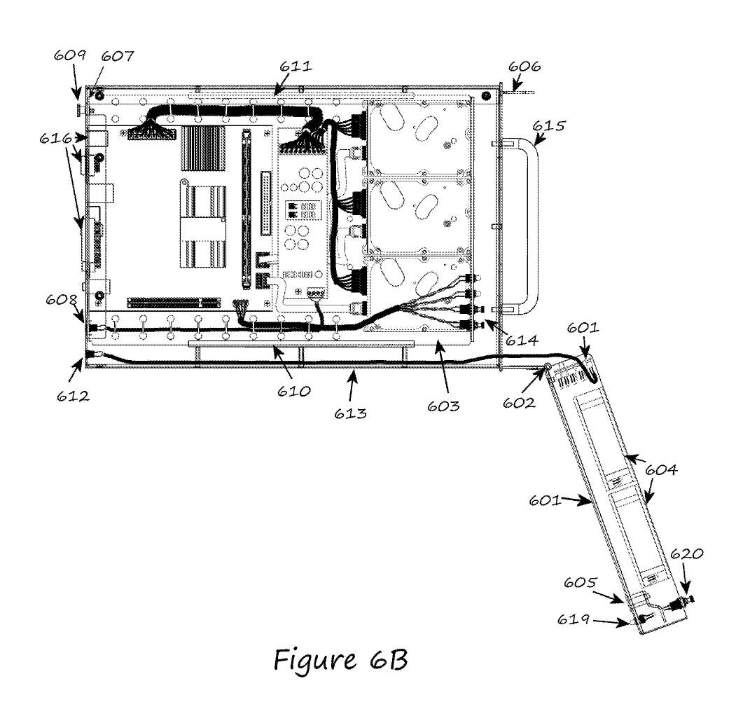

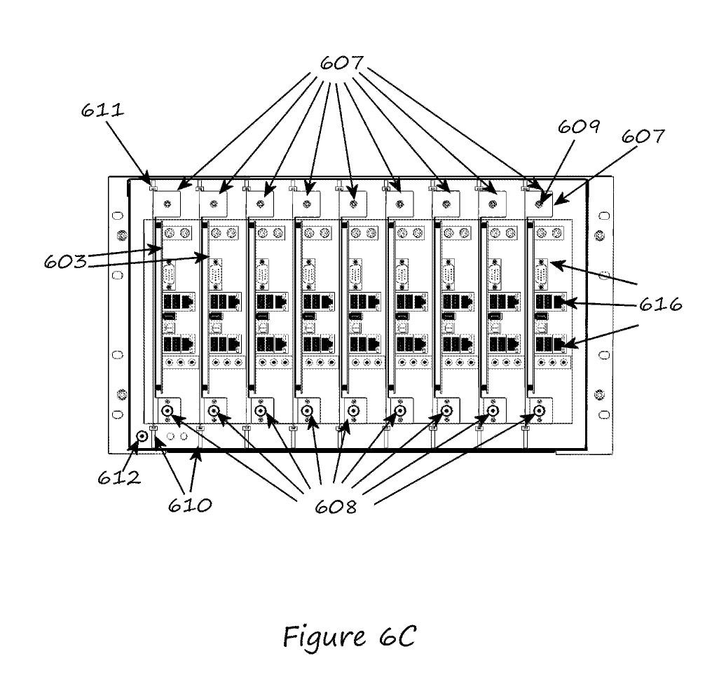

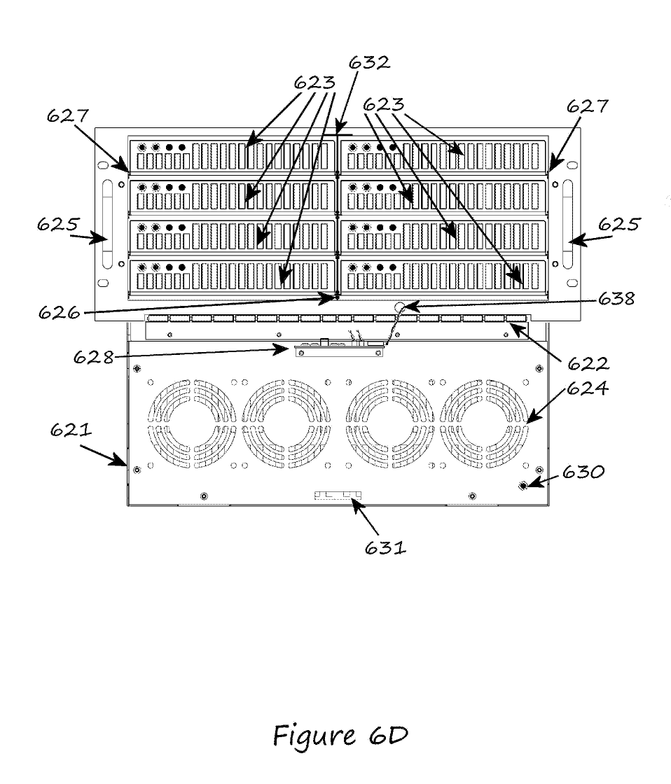

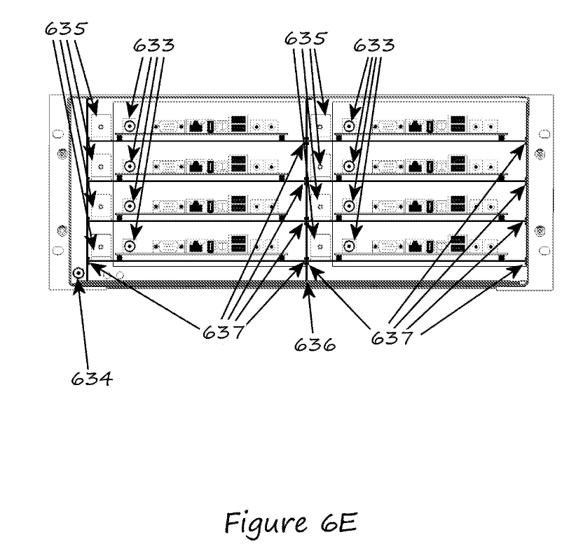

In the present embodiment, power supply shelf 201 comprises a single piece of metal, bent to create tabs 202 for rack mounting as well as providing rows of holes 203 for securing a brick style 240/120 Volts AC to 12 Volts DC power supply unit 205 utilizing wire-tie straps 206 to the shelf. A multiplicity of holes 203 is provided, without limitation, to enable multiple power supply units and power supply units of different shapes and sizes to be mounted to power supply shelf 201. Power supply shelf 201 comprises additional rows of holes 204 for wire management via wire ties 207. Power cables terminate with a coaxial power plug 208 which can be inserted into either the blade tray holding chassis coaxial power receptacle, illustrated by way of example in FIGS. 1B, 6B,6C. and 6E, or any of the coaxial power receptacles on the blade trays, illustrated by way of example in FIGS. 6B, 6C, and 6E. This interchangeability improves serviceability, requiring only one power supply type for the entire system if the system is operated on 240/120 AC mains voltages via a standard power plug and cable 209. This enables the end user to keep one type of non-proprietary power supply that may be sourced from many different manufacturers on hand for servicing.

In the present embodiment, DC power distribution box 210 comprises a four sided box of metal, with tabs 214 for rack mounting. DC power is supplied to the power distribution box 210, by way of cables from alternate power sources, illustrated by way of example in FIG. 3B. The DC power positive and negative polarity cables 212 are attached to the power distribution box 210 by way of a screw terminal strip 211. DC power is then distributed internally via wiring within the DC power distribution box 210 by means of a power cable to be individually fused for safety using bulkhead mounted fuse holders 213. DC Power cables terminate with a coaxial power plug 215 which can be inserted into either the blade tray holding chassis coaxial power receptacle, illustrated by way of example in FIGS. 1B, 6B,6C, and 6E, or any of the coaxial power receptacles on the blade trays, illustrated by way of example in FIGS. 6B,6C, and 6E.

FIG. 3A is a cross sectional side view of an exemplary modular blade system in use with a typical rack-mounting system 301, powered by typical 120/240 volt AC wall power using AC power cable and plug 302, connected to a typical 120/240 volt AC power wall socket 307, in accordance with an embodiment of the present invention. In the present embodiment a blade tray holding chassis 303 is typically less in rack depth than many existing blade computing systems, which provides space to separate a power supply shelf 304 from blade tray holding chassis 303 and mount power supply shelf 304 on the rear of rack mounting system 301. Normally, power supplies are integrated into the same chassis as the computer components. Power supply shelf 304 allows for multiple AC to DC power supplies to be mounted behind blade tray holding chassis 303, each supplying power for a single blade tray via cabling 305 from power supply shelf 304 to blade tray holding chassis 303. This allows for increased efficiency in cooling, quick interchangeability as well as increased reliability over many existing blade computing systems that have a common integrated power supply unit powering all blade trays over a common power buss. Should that power supply fail in these existing systems, all blade trays are affected. The present embodiment provides for independent power where a single failure affects only one blade tray at a time. If a power supply fails, the end user only needs to repair or replace that power supply, and the end user does not need to remove the blade tray to perform this repair replacement, thus reducing repair time. In addition, since power supply shelf 304 is separate from blade tray holding chassis 303, no waste heat from AC to DC power conversion is present near the computing components. This further enhances cooling efficiency. The air flow direction of blade tray holding chassis 303 while mounted in rack mounting system 301 matches the industry standard air flow pattern, flowing from the front of rack 301 to the rear of rack 301 as shown by way of example by an arrow 306.

FIG. 3B is a cross sectional side view of an exemplary modular blade system in use with a typical rack-mounting system 314, powered by alternate power sources exemplified by a DC power wind turbine 309 and DC power photovoltaic solar panels 308. DC power from wind turbine 309 and photovoltaic solar panels 308 is distributed by DC power cables 310 to a power junction box 311, which combines all DC power sources to a unified DC power cable 312, connected to DC power distribution box 313. In the present embodiment a blade tray holding chassis 315 is typically less in rack depth than many existing blade computing systems, which provides space to mount the separate DC power distribution box 313 from blade tray holding chassis 315 and mount DC power distribution box 313 on the rear of rack mounting system 314. Normally, power supplies are integrated into the same chassis as the computer components. DC power distribution box 313 allows for multiple DC power connections to be available behind blade tray holding chassis 315, each supplying power for a single blade tray via cabling 316 from DC power distribution box 313 to blade tray holding chassis 315. The This alternate DC power distribution allows for operation in remote areas or mobile implementations where standard 120/240 volt AC mains power is unavailable, and offers increased efficiency in cooling, since no waste heat in generated in DC power distribution. The air flow direction of blade tray holding chassis 315 while mounted in rack mounting system 314 matches the industry standard air flow pattern, flowing from the front of rack 314 to the rear of rack 314 as shown by way of example by an arrow 317.

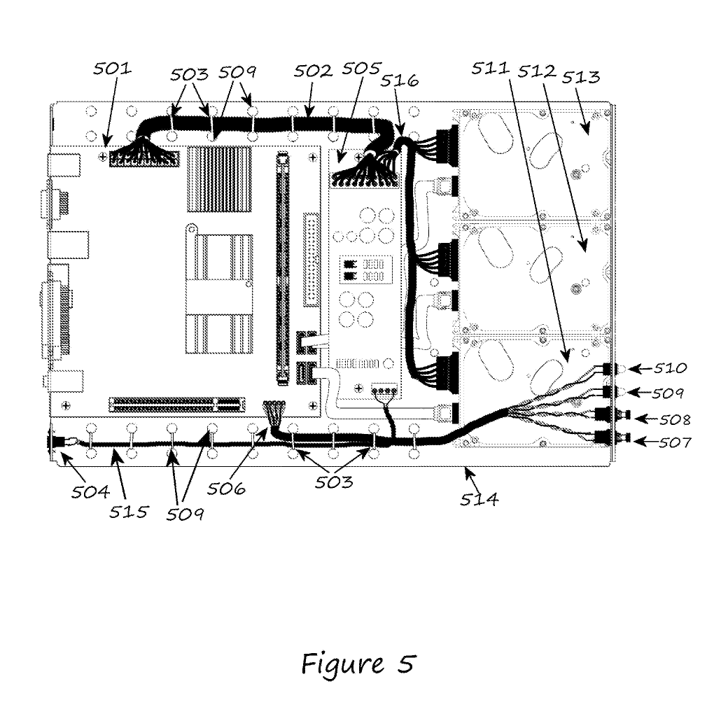

FIG. 4 is a side perspective view of an exemplary blade tray, in accordance with an embodiment of the present invention. In the present embodiment, the blade tray comprises a single piece of metal with one bend to form a front panel 401 with additional bends for a tray securing tab 402 and for a power connector tab 403, making fabrication simple and lowering manufacturing cost compared to individually fabricated metal elements. Some alternate embodiments may be made from various different materials such as, but not limited to, suitable plastic materials. Previous blade designs use discrete and multiple metal elements to create the tray holding and securing components. The single metal blade tray design of the present embodiment also combines the utility for control panel lights and switches to be mounted through mounting holes 404, a front fascia air flow grating 405, 12 mounting holes 406 for three mounting locations, four holes 406 each, for industry standard 2.5 inch hard disk drives, and optional mounting holes 407 for a single industry standard 3.5 inch hard disk drive. Some alternate embodiments may comprise mounting locations for a multiplicity of suitable hard disk drives of different sizes. In the present embodiment, the blade tray also comprises integrated screw standoffs 408 for increased airflow when mounting a 12 volt DC to multiple DC power inverter board to power a motherboard with all required voltages. Three rows of wiring management holes 409 on the top and bottom of the blade tray, and between the disk driving mounting area and the DC-DC power converter, are provided for securing internal wiring with wire tie straps, as shown by way of example in FIG. 5. The blade tray comprises integrated screw standoffs 410 in a pattern fitting the mounting hole pattern for an industry standard Mini-ITX computer motherboard. Some alternate embodiments may be configured for mounting various different industry standard motherboards or for mounting custom motherboards. In the present embodiment, top and bottom edges 413 of the blade tray serve as the tongues to insert into the grooves of a mounting rail, as shown by way of example in FIGS. 6B and 6C, in any position of the blade tray holding chassis. Edges 413 of the blade tray are rounded to enable easy insertion into the mounting rails. A mounting hole 414 is provided for a DC coaxial power connector to provide external power to the entire blade tray assembly. A threaded hole 415 in tab 403 is provided to secure the blade tray assembly in the rear of a blade tray holding chassis with a thumbscrew.

FIG. 5 is a side view of exemplary computer components mounted to a blade tray 514, in accordance with an embodiment of the present invention. In the present embodiment, blade tray 514 includes, without limitation, an integrated DC to DC power converter board 505 that converts the 12 volts DC power typically supplied to blade tray 514 to all of the different required voltages needed for a Mini ITX motherboard 501 and peripheral components such as, but not limited to, hard drives 511, 512 and 513. A DC coaxial power connector 504 enables an external power supply to be connected to blade tray 514 by a coaxial power plug, as illustrated by way of example in FIG. 2, to provide power to the entire blade tray assembly. A single two-wire cable 515 transmits the 12 volts DC power from the rear tray connector to DC to DC power converter board 505 integrated into blade tray 514. Power converter board 505 enables blade tray 514 to operate on mobile DC power, standard 240/120 VAC mains power, as in a traditional server room, or alternate power sources. Conventional Mini-ITX blade systems are generally designed for 240/120 VAC power only. DC to DC power converter board 505 is of a standard established design for Mini-ITX motherboards, with a standardized hole-mounting dimension and size, available from many different manufacturers. In some alternate embodiments, the DC-to-DC power converter board can be changed to handle different power requirements, for example, without limitation, to accommodate higher power motherboards if need be. By the same design feature, larger 120 VAC to 12-volt DC external power converters can be used in some alternate embodiments if desired. In the present embodiment, converted power is distributed via a wiring harness 502 to Mini ITX motherboard 501 and by a wiring harness 516 to hard drives 511, 512 and 513. Blade tray 514 comprises a power on/off switch 507, a reset switch 508, a power status LED 509, and a hard disk activity indicator LED 510. An interface between the front panel controls and Mini ITX motherboard 501 is supplied by a wiring harness 506. Those skilled in the art, in light of the teachings of the present invention will readily recognize that alternate embodiments may comprise a multiplicity of suitable additional or alternate front panel controls such as, but not limited to, connectivity indicators, temperature readings, clocks, etc. In the present embodiment, wiring harnesses 502 and 506 are secured via wire ties 503 utilizing rows of wire management holes 509. All data interface and power connectors are at the rear of blade tray 514. This orientation follows industry accepted practices, where all computer interface and power wiring is at the rear of the blade tray holding chassis, which allows for unimpeded removal and servicing of blade tray 514 from the front of the chassis. Some other Mini ITX blade system designs in service today have not followed this industry standard convention.

In the present embodiment, blade tray 514 uses industry standard computer components, specifically the industry standard Mini-ITX computer motherboard form 501, mounted on screw standoffs that match the industry standard Mini-ITX motherboard mounting hole pattern allowing for a wide variety of configurations based on available motherboard sources and processor/memory sub-components. Unlike many previous blade computer designs where each blade is homogenous in processor and motherboard type, blade tray 514 allows for motherboards, processors, memory, hard drives, in unlimited configurations, allowing the blade tray holding chassis to host computer blade trays of radically different design, computing power, and storage capacity all in a single rack mounted space. This provides added computing flexibility for the end-user. The single piece design of blade tray 514 provides all needed utility for a complete computer server, while allowing for generous, uninhibited airflow across blade tray 514 from the front to the rear.

FIGS. 6A, 6B, and 6C illustrate an exemplary blade tray holding chassis holding multiple blade trays with a hinged door assembly 601 in an open position, in accordance with an embodiment of the present invention. FIGS. 6D and 6E show alternate configurations using the Thin Mini-ITX form factor. For Mini-ITX configurations, FIG. 6A is a front view. FIG. 6B is a cross sectional side view, and FIG. 6C is a diagrammatic rear view. For Thin Mini-ITX configurations, FIG. 6D is a front view and FIG. 6E is a diagrammatic rear view. In the present Mini-ITX embodiment, the blade tray holding chassis holds 9 complete blade trays 603 in a 6 RU (rack unit) space, improving typical rack density. Normally the density is 1 computer per 1 RU of rack space. Referring to FIGS. 6A and 6B, a hinge 602 enables hinged door assembly 601 to open and close. All front panel controls 614 for each computer system occupying each blade tray 603 are accessible from the front of the blade tray holding chassis while door assembly 601 is open. Referring to FIGS. 6B and 6C, blade trays 603 are mounted on lower mounting rails 610 and upper mounting rails 611 by inserting the bottom and top edges of blade trays 603 into grooves in mounting rails 610 and 611. Once blade trays 603 are inserted into the grooves of mounting rails 610 and 611, thumbscrews 609 may be used to attach tabs 607 of blade trays 603 to rear of the blade tray holding chassis. The open design of the blade tray holding chassis and blade trays 603 provides unimpeded access to rear connectors 616 on components attached to blade trays 603.

Referring to FIG. 6A, hinged door assembly 601 comprising cooling fans 604 can be secured in a closed position by a key and tab lock assembly 605 which fits into a tab 606 on the blade tray holding chassis. Referring to FIGS. 6A and 6B, handles 615 enable blade tray holding chassis to be easily handled by a single user. In the present embodiment, an audible and visual electronic alarming system is built into hinged door assembly 601 for fan function and for measuring the internal temperature of the blade tray holding chassis. This alarm system detects fan failure using a sensor 618 on hinged door assembly 601 as well as over-temperature conditions using two temperature sensors placed inside the chassis. An audible alarm sounds and an LED indicator 619 flashes if a fan failure or over-temperature condition occurs. An alarm reset switch 620 is provided inside hinged door assembly 601. Referring to FIGS. 6B and 6C, power is supplied through a wire 613 by a coaxial power connector 612 wired to a standard 4-pin molex style connector via a plug provided to power the entire blade tray holding chassis at the rear, which also powers cooling fans 604. Each blade tray 603 also comprises a coaxial power connector 608. Power connectors 608 and 612 are industry standard DC coaxial power connectors. This allows easy substitution of any 12-volt DC power source with a matching connector, for example, without limitation, any standard coaxial male power plug. It is contemplated that various different power connectors may be used in some alternate embodiments of the present invention.

In the present Thin Mini-ITX form factor embodiment the blade tray holding chassis holds 8 complete blade trays 623 in a 4 RU (rack unit) space, doubling typical rack density. FIG. 6D provides a front exemplary view where the blade trays, reduced in height to meet the Thin Mini-ITX format dimensions, are oriented horizontally for a higher density placement in a smaller rack-mounted space than the Mini-ITX embodiment.

In the present Thin Mini-ITX embodiment, the Thin Mini-ITX standard designates that the computer motherboard in that form factor shall have a DC to DC power converter on the computer motherboard, thus negating the need for a separate DC to DC power converter board as shown in the Mini-ITX tray configuration 505. FIG. 6E illustrates a typical Thin Mini-ITX edge view, and the DC coaxial power connectors 633 are physically on the motherboards. The coaxial power connector for the blade tray holding chassis 634 is identical so that power supplies from the power supply shelf or the DC power distribution box 313 are interchangeable with the standard Mini-ITX embodiment. In FIGS. 6D and 6E, Thin Mini-ITX blade trays 623 and 635 are mounted horizontally, suspended by guide rails 627 and 637 which contact the edges of the blade tray cards. Blade trays The rails are secured to a center divider 632 and 636 and to the side walls of the blade tray holding chassis. Hinged 622 door assembly 621 comprising cooling fans 624 can be secured in a closed position by a key and tab lock assembly 631 which fits into a tab 632 on the blade tray holding chassis. Handles 625 enable blade tray holding chassis to be easily handled by a single user. In the present Thin Mini-ITX embodiment, an audible and visual electronic alarming system is built into hinged door assembly 621 for fan function and for measuring the internal temperature of the blade tray holding chassis. This alarm system detects fan failure using a sensor 628 on hinged door assembly 621 as well as over-temperature conditions using two temperature sensors placed inside the chassis. An alarm reset switch 630 is provided inside hinged door assembly 621. Power is supplied through a wire 623 by a coaxial power connector 634 wired to a standard 4-pin molex style connector via a plug provided to power the entire blade tray holding chassis at the rear, which also powers cooling fans 624.

In the present Mini-ITX and also the Thin Mini-ITX embodiment, blade trays 603 and 623 are not enclosed. Furthermore, the blade tray holding chassis does not require ducting of airflow for cooling. Instead, fans 604 and 624 provide simple front to rear forced air cooling, which is efficient. Also, because blade trays 603 and 623 are suspended in the blade tray holding chassis, “hotspots” created by dead air pockets that can develop in conventional, enclosed blade trays are generally eliminated. In addition, industry standard practice for blade system design typically calls for access to controls and removal of blades at the front of the chassis, power and data cables at rear so that the cables may be enclosed neatly in the rack cabinet, and airflow from the front to the rear. Of the blade servers that currently exist for the Mini-ITX motherboard platform, many are reversed over normal practice with the cables located in the front and the fans in the rear. This makes deployment of these systems troublesome. The present embodiment conforms to these industry practices.

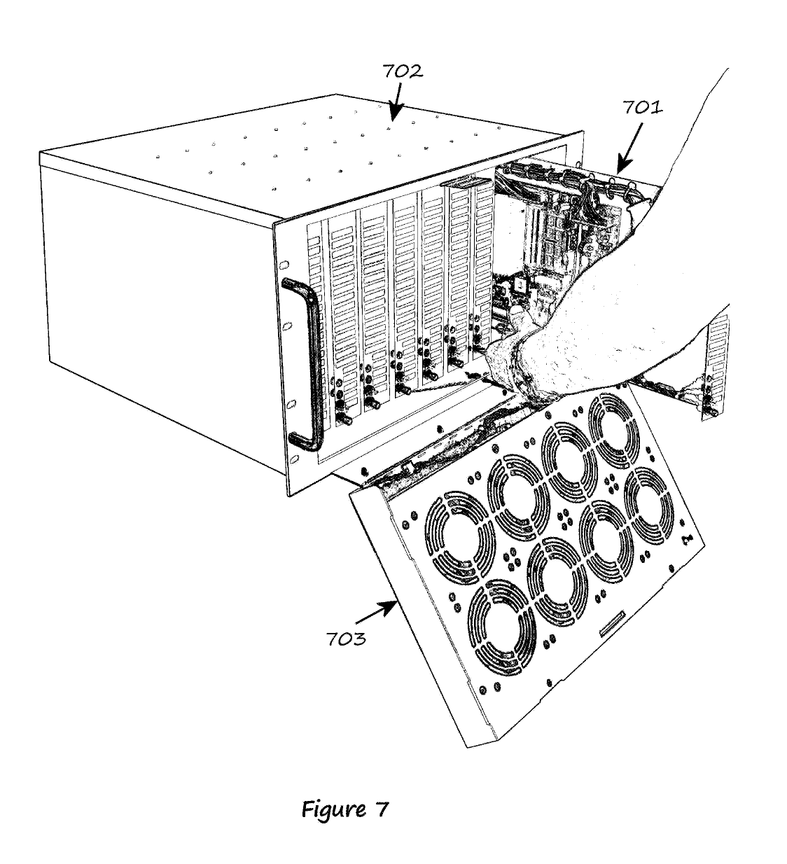

FIG. 7 illustrates an exemplary blade tray 701 being removed from a blade tray holding chassis 702, in accordance with an embodiment of the present invention. In the present embodiment, blade tray 701, along with any other blade tray mounted within blade tray holding chassis 702, can be serviced while the system is operational by unlocking the lock on a hinged door assembly 703, swinging door assembly 703 to the full open position, as illustrated by way of example in FIG. 7, and removing blade tray 701 from the front of chassis 702 by sliding it forward. Blade tray 701 comprises an open frame design and allows for immediate removal and access for servicing of all computing components while other blade trays remain in operation. This open design generally improves the speed of computing component serviceability. This also allows for “upgrades in place” while the system is operational. Because blade tray 701 utilizes industry standard computer components, the end user can retain chassis 702 over a long period of time and maintain an up to date system, by simply removing blade tray 701 and upgrading the industry standard computer components as technology advances. This allows the total cost of ownership to be reduced, it also allows for reduced recycling, making the system “greener” in its use of materials. Previous homogenous blade designs generally require a complete system replacement (i.e., housing and blades) as they reach the ends of their lives, and current designs from major manufacturers generally use a fixed computer components list, often proprietary. The present embodiment provides an open access system in which a wide variety of parts from different manufacturers can be used (i.e., non-homogenous system). This allows for flexibility, serviceability, and a longer return on investment. This interchangeability applies to the various components including, without limitation, power supplies, DC-to-DC converters, switches and cables as well as the computer components. The blade tray holding chassis and blade trays in the present embodiment can accommodate thousands of design variations with no need to purchase any proprietary computer components.

All the features disclosed in this specification, including any accompanying abstract and drawings, may be replaced by alternative features serving the same, equivalent or similar purpose, unless expressly stated otherwise. Thus, unless expressly stated otherwise, each feature disclosed is one example only of a generic series of equivalent or similar features.

Having fully described at least one embodiment of the present invention, other equivalent or alternative methods of providing modular blade systems according to the present invention will be apparent to those skilled in the art. The invention has been described above by way of illustration, and the specific embodiments disclosed are not intended to limit the invention to the particular forms disclosed. For example, the particular implementation of the components may vary depending upon the particular type of system being used. The systems described in the foregoing were directed to server implementations; however, similar techniques are to provide modular blade systems for various different rack-mounted computing systems such as, but not limited to, rack-mounted PCs, industrial computers, network attached storage (NAS) systems, etc. Non-server implementations of the present invention are contemplated as within the scope of the present invention. The invention is thus to cover all modifications, equivalents, and alternatives falling within the spirit and scope of the following claims.

Claim elements and steps herein may have been numbered and/or lettered solely as an aid in readability and understanding. Any such numbering and lettering in itself is not intended to and should not be taken to indicate the ordering of elements and/or steps in the claims.

What is claimed is:

1. A server comprising:
a holding chassis comprising:
a front open end;
a back open end;
a cable interface access area being disposed in the back open end;
at least one fan being disposed in the front open end, the at least one fan being configured to force air from the front open end to the back open end;
and a computer rack mounting system being configured to hold a plurality of computers;
a blade tray being configured to be removably joined to the computer rack mounting system by insertion through said front open end, the blade tray comprising a computer and a DC to DC power converter; and
a power supply shelf being configured to hold at least a first AC to DC power supply being in communication with the blade tray and a second AC to DC power supply being in communication with the fan.

2. The server of claim 1, in which the blade tray further comprises one metal sheet, the metal sheet comprising a top, a bottom and a plurality of sides.

3. The server of claim 2, in which the top and bottom comprise tongues, the tongues being configured to join with the rack mounting system.

4. The server of claim 1, in which the holding chassis further comprises a plurality of mount brackets, each mount bracket configured to attach to a rack-mounting system.

5. The server of claim 1, in which the holding chassis further comprises a plurality of mounting cutouts, each mounting cutout being configured to a fan.

6. The server of claim 5, further comprising a hinged door assembly joined to the front open end of holding chassis, the hinged door assembly comprising the mounting cutouts and a lock assembly.

8. The server of claim 1, in which the power supply shelf further comprises one piece of metal, the piece of metal comprising a plurality of tabs, and a plurality of holes, the holes being configured to hold power supplies and wiring.

9. The server of claim 1, in which the blade tray comprises a Mini-ITX form factor motherboard.

10. The server of claim 1, in which the blade tray further comprises a plurality of integrated screw standoffs, each integrated screw standoff being configured to increase airflow about the computer.

11. The server of claim 1, in which the blade tray further comprises a switch comprising an on position and an off position, a reset switch, a light emitting diode being configured to indicate the on position of the switch, and a hard disk activity indicator light emitting diode.

12. The server of claim 1, further comprising at least one of a connectivity indicator, a temperature indicator, or a clock.

13. A server comprising:
a holding chassis comprising:
a front open end;
a back open end; and
a computer rack mounting system being configured to hold a plurality of computers;
a blade tray comprising:
one metal sheet, the metal sheet comprising a top, a bottom and a plurality of sides, the metal sheet being configured to be removably joined to the computer rack mounting system; and
a computer; and
a power supply shelf configured to hold at least one AC to DC power supply, the AC to DC power supply being in communication with the blade tray.

14. The server of claim 13, in which the holding chassis further comprises a hinged door assembly being joined to the front open end, the hinged door assembly comprising a closed position, an opened position, a lock assembly, and a fan being configured to force air from the front open end to the back open end.

15. The server of claim 14, in which the hinged door assembly further comprises an electronic alarm system, the electronic alarm system comprising an audible alert mechanism and a visual alert mechanism.

16. The server of claim 15, in which the electronic alarm system further comprises an alarm reset switch disposed in the hinged door assembly, and in which the visual alert mechanism comprises a light emitting diode, and in which the visual alert mechanism and the audible alert mechanism are each being configured to indicate at least one of a temperature increase or a fan failure.

17. The server of claim 13, in which the holding chassis further comprises a cable interface area being disposed in the back open end.

18. The server of claim 13, further comprising at least one of a connectivity indicator, a temperature indicator, or a clock.

19. A server comprising:
means for holding a plurality of computers in a rack configuration;
means for holding a computer and a DC to DC power converter to be removably joinable to the means for holding a plurality of computers; and
means for holding at least one DC power supply separate from the means for holding a plurality of computers.

20. The server of claim 19, further comprising means for forcing air through the means for holding a plurality of computers.
